(19) United States
(12) Patent Application Publication
(10) Pub. No.: US 2019/0074251 A1
(43) Pub. Date: Mar. 7, 2019

(54) SEMICONDUCTOR PACKAGES

(71) Applicant: Samsung Electronics Co., Ltd., Suwon-si (KR)

(72) Inventors: Hee-won Kang, Hwaseong-si (KR); Jong-joo Lee, Hwaseong-si (KR); Byeong-uk Jeon, Suwon-si (KR)

(21) Appl. No.: 15/963,248

(22) Filed: Apr. 26, 2018

(30) Foreign Application Priority Data
Sep. 1, 2017 (KR) 10-2017-0111927

(51) Int. Cl. H01L 23/552; H01L 21/66; H01L 23/31; H01L 23/538; H01L 23/00

(52) U.S. Cl. CPC H01L 23/552; H01L 22/32; H01L 23/3114; H01L 23/3128; H01L 2224/214; H01L 23/5386; H01L 23/5389; H01L 24/20; H01L 2924/3025; H01L 23/5383

(57) ABSTRACT

Semiconductor packages are provided. A semiconductor package includes a package base substrate that includes a base layer. A plurality of connection terminals are on the base layer. Moreover, a plurality of electromagnetic shielding terminals are on the base layer around the plurality of connection terminals. The semiconductor package includes a package body that includes at least one semiconductor chip. The semiconductor package includes an electromagnetic shielding layer on the package base substrate and on the package body.

### CROSS-REFERENCE TO RELATED APPLICATION

This application claims the benefit of Korean Patent Application No. 10-2017-0111927, filed on Sep. 1, 2017, in the Korean Intellectual Property Office, the disclosure of which is hereby incorporated herein in its entirety by reference.

### BACKGROUND

The present disclosure relates to semiconductor packages. As the electronics industry rapidly advances and the demands of users increase, electronic devices are becoming higher in performance and becoming more and more miniaturized, and thus, semiconductor packages each including an electromagnetic shielding member for shielding electromagnetic interference (EMI) between elements included in the electronic devices are being developed.

### SUMMARY

Various embodiments of the present inventive concepts provide a semiconductor package which may shield an electromagnetic wave and may be miniaturized.

According to some embodiments of the present inventive concepts, a semiconductor package may include a package base substrate that includes a base layer. A plurality of connection terminals may be on a first side of the base layer. Moreover, a plurality of electromagnetic shielding terminals may be spaced apart from one another on the first side of the base layer to provide a perimeter around the plurality of connection terminals. The semiconductor package may include a package body on a second side of the base layer that is opposite the first side, and the package body may include at least one semiconductor chip. Moreover, the semiconductor package may include an electromagnetic shielding layer on a surface of the package base substrate and on first and second surfaces of the package body. A value of a shortest distance between the plurality of connection terminals and the plurality of electromagnetic shielding terminals may be equal to or higher than a separation distance between two adjacent ones of the plurality of electromagnetic shielding terminals.

A semiconductor package, according to some embodiments of the present inventive concepts, may include a package base substrate including a bridge region, a fence region around the bridge region, a spacing region between the bridge region and the fence region, an edge region around the fence region, and a base layer. A plurality of connection terminals may be on a lower surface of the base layer. The semiconductor package may include a ground plate layer on an end portion of the lower surface of the base layer. Moreover, a plurality of electromagnetic shielding terminals may be electrically connected to the ground plate layer in the fence region around the plurality of connection terminals. The semiconductor package may include a package body on the package base substrate. The package body may include a plurality of semiconductor chips. Moreover, the semiconductor package may include an electromagnetic shielding layer on a side surface of the package base substrate and a side surface and an upper surface of the package body. The electromagnetic shielding layer may contact a side surface of the ground plate layer. A width of the spacing region may be equal to or greater than a separation distance between two adjacent ones of the plurality of electromagnetic shielding terminals.

A semiconductor package, according to some embodiments of the present inventive concepts, may include a package base substrate including a base layer. A plurality of connection terminals may be on a bottom of the base layer to provide a ball map. A ground plate layer may be on the bottom of the base layer, and a plurality of electromagnetic shielding terminals may be attached to a bottom of the ground plate layer. The plurality of electromagnetic shielding terminals may be spaced apart from one another to provide a ground fence around the ball map. The semiconductor package may include a package body on the package base substrate. The package body may include a plurality of semiconductor chips and an encapsulation layer that is on a top of the package base substrate and is on the plurality of semiconductor chips. Moreover, the semiconductor package may include an electromagnetic shielding layer on a side surface of the package base substrate and a side surface and a top of the package body. The electromagnetic shielding layer may contact the ground plate layer. A shortest distance between the ball map and the ground fence may be equal to or greater than a separation distance between two adjacent ones of the plurality of electromagnetic shielding terminals.

### BRIEF DESCRIPTION OF THE DRAWINGS

Embodiments of the present inventive concepts will be more clearly understood from the following detailed description taken in conjunction with the accompanying drawings in which:

FIG. 1A is a cross-sectional view illustrating a semiconductor package attached on a set board according to some embodiments;

FIGS. 1B to 1D are cross-sectional views illustrating a semiconductor package according to some embodiments;

FIGS. 2A to 2F are bottom views illustrating a main part of a semiconductor package according to some embodiments;

FIG. 3 is a cross-sectional view illustrating a semiconductor package according to some embodiments;

FIGS. 4A and 4B are bottom views illustrating a main part of a semiconductor package according to some embodiments;

FIG. 5 is a cross-sectional view illustrating a semiconductor package according to some embodiments;

FIG. 6 is a bottom view illustrating a main part of a semiconductor package according to some embodiments;

FIGS. 7A to 7D are bottom views illustrating a main part of a semiconductor package according to some embodiments; and

FIGS. 8 and 9 are schematic views illustrating a relationship between an external system and a semiconductor package according to some embodiments.

### DETAILED DESCRIPTION

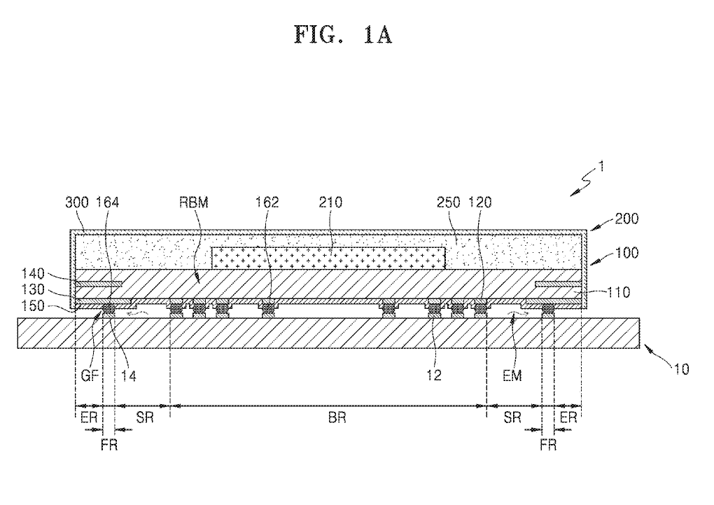

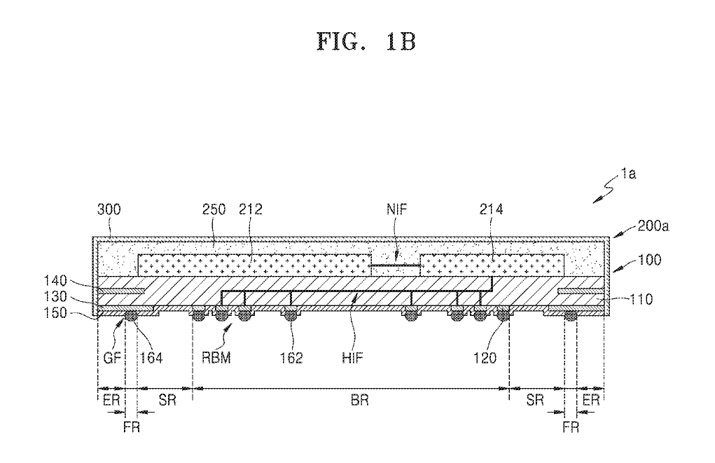

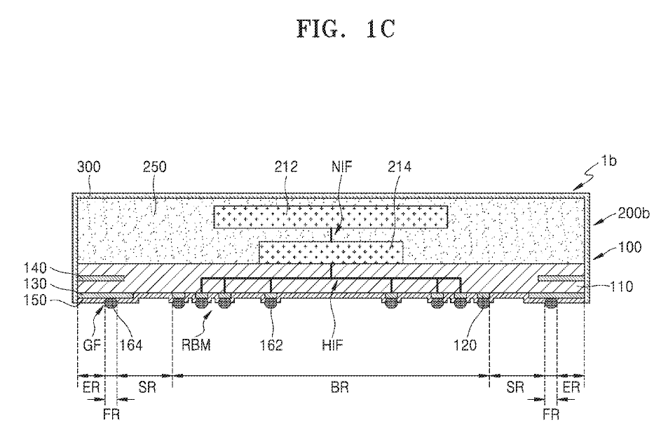

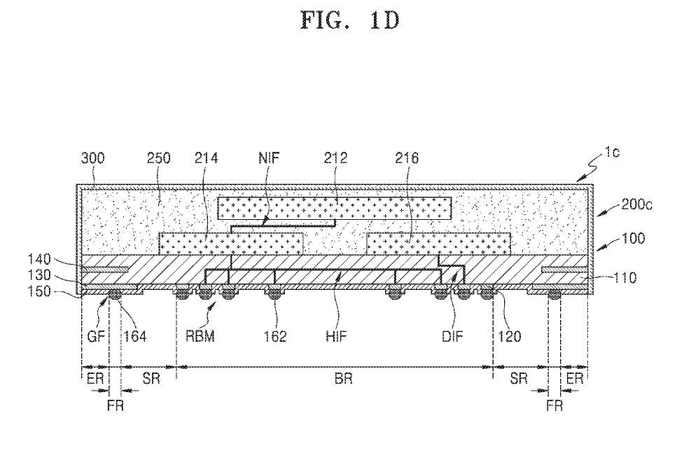

FIG. 1A is a cross-sectional view illustrating a semiconductor package 1 attached on a set board according to some embodiments.

Referring to FIG. 1A, the semiconductor package 1 may be attached on a set board 10. The set board 10 may include a first connector 12 and a second connector 14. The semiconductor package 1 may exchange a data signal or may be supplied with a control signal, a clock signal, and power/ground that may be used (e.g., necessary) for an operation of the semiconductor package 1, through the first connector 12. The semiconductor package 1 may be supplied with, through the second connector 14, the ground used (e.g., necessary) for shielding an electromagnetic wave.

In some embodiments, the set board 10 may be a printed circuit board (PCB), and each of the first and second connectors 12 and 14 may be a connection pad disposed on one surface of the PCB. However, the present inventive concepts are not limited thereto. In some embodiments, the set board 10 may be an element or a portion of the element, which the semiconductor package 1 is attached on and electrically connected to, of elements included in an electronic device including the semiconductor package 1. For example, the set board 10 may be another semiconductor package which the semiconductor package 1 is attached on and electrically connected to. In some embodiments, the set board 10 may be a bottom semiconductor package configuring/providing a package-on-package (PoP) type semiconductor package, and the semiconductor package 1 may be a top semiconductor package configuring/providing the PoP type semiconductor package.

The semiconductor package 1 may include a bridge region BR, a fence region FR surrounding the bridge region BR, a spacing region SR between the bridge region BR and the fence region FR, and an edge region ER between an edge of the semiconductor package 1 and the fence region FR. The spacing region SR may surround the bridge region BR. The fence region FR may surround the bridge region BR and the spacing region SR. The edge region ER may surround the bridge region BR, the spacing region SR, and the fence region FR.

The semiconductor package 1 may include a package base substrate 100, a package body 200 mounted on the package base substrate 100, and an electromagnetic shielding member (e.g., layer) 300 on (e.g., covering) at least a portion of a surface of each of the package base substrate 100 and the package body 200.

In some embodiments, the package base substrate 100 may be a PCB. For example, the package base substrate 100 may be a double-sided PCB or a multi-layer PCB. The package base substrate 100 may include at least one base layer 110, a plurality of top connection pads disposed on a top of the package base substrate 100, and a plurality of bottom connection pads 120 disposed on a bottom of the package base substrate 100. A top solder resist layer and a bottom solder resist layer 150 may be respectively disposed on a top and a bottom of the base layer 110. The plurality of bottom connection pads 120 may be exposed by the bottom of the package base substrate 100 without being covered by the bottom solder resist layer 150. In some embodiments, the top solder resist layer may be omitted by not being disposed on the top of the package base substrate 100. In some embodiments, the package base substrate 100 may include a plurality of base layers 110 which are stacked. In some embodiments, the at least one base layer 110 may include at least one material selected from among phenol resin, epoxy resin, and polyimide.

A connection terminal 162 may be attached on a respective/corresponding bottom connection pad of the bottom connection pads 120. The connection terminal 162 may be, for example, a solder ball or a bump. The connection terminal 162 may be attached on the first connector 12 of the set board 10 and may electrically connect the semiconductor package 1 to the set board 10. The connection terminal 162 may be provided in plurality, and the plurality of connection terminals 162 may transfer a data signal between a semiconductor chip 210 and the set board 10 or may provide a control signal, a clock signal, and power/ground, which may be used (e.g., necessary) for an operation of the semiconductor chip 210, to the semiconductor chip 210. The plurality of connection terminals 162 may configure/provide a ball map, such as a real ball map RBM, that may be used (e.g., necessary) for an operation of the semiconductor package 1 including the semiconductor chip 210. In some embodiments, the plurality of connection terminals 162 configuring/providing the real ball map RBM may be arranged according to the joint electron device engineering council (JEDEC) standard. In some embodiments, the number of the connection terminals 162 configuring/providing the real ball map RBM may be 153, but is not limited thereto.

A ground plate layer 130 may be disposed on a bottom (e.g., a lower surface) of the base layer 110. The ground plate layer 130 may extend horizontally from an edge (e.g., an end portion) of the bottom of the base layer 110 to (e.g., toward/along) the inside (e.g., an inner portion) of the bottom of the base layer 110 and may be on (e.g., may cover) a portion of the bottom of the base layer 110. The ground plate layer 130 may extend along the edge of the bottom of the base layer 110 and may surround the bridge region BR. A portion of the ground plate layer 130 may be covered by the bottom solder resist layer 150. The bottom solder resist layer 150 on the bottom of the ground plate layer 130 may not cover a portion of the fence region FR. An electromagnetic shielding terminal 164 may be attached on a portion of the ground plate layer 130 uncovered by the bottom solder resist layer 150. For example, a plurality of electromagnetic shielding terminals 164 may be electrically connected to the electromagnetic shielding member 300 through the ground plate layer 130. The plurality of connection terminals 162, on the other hand, may be electrically isolated from the electromagnetic shielding member 300 and the ground plate layer 130. The ground plate layer 130 and the bottom connection pads 120 may include the same material. The ground plate layer 130 and the bottom connection pads 120 may include, for example, copper.

The bottom solder resist layer 150 may be on (e.g., may cover) a bottom of a portion, disposed in each of the edge region ER and the spacing region SR, of the ground plate layer 130 and a bottom of a portion, on which the electromagnetic shielding terminal 164 is not attached, of the fence region FR.

The electromagnetic shielding terminal 164 may be spaced apart from an edge of the base layer 110 with the edge region ER therebetween. The electromagnetic shielding terminal 164 may be, for example, a solder ball or a bump. The electromagnetic shielding terminal 164 may be attached on the second connector 14 of the set board 10 and may be supplied with ground that may be used (e.g., necessary) for shielding an electromagnetic wave.

The electromagnetic shielding terminal 164 may be provided in plurality, and the plurality of electromagnetic shielding terminals 164 may be disposed to surround the real ball map RBM including the plurality of connection terminals 162 to configure a ground fence GF. The ground fence GF configured/provided by the plurality of electromagnetic shielding terminals 164 may be spaced apart from the real ball map RBM including the plurality of connection terminals 162 with the spacing region SR therebetween. Although the term “surround” is used herein to describe various examples, it will be understood that some elements may not continuously/completely surround other elements. For example, the plurality of electromagnetic shielding terminals 164 may be spaced apart from each other to define/provide a perimeter around the plurality of connection terminals 162 without continuously/completely surrounding the plurality of connection terminals 162.

The electromagnetic shielding terminals 164 and the connection terminals 162 may include the same material. In some embodiments, the electromagnetic shielding terminals 164 and the connection terminals 162 may substantially have the same shape. For example, the electromagnetic shielding terminals 164 and the connection terminals 162 may be formed by the same manufacturing process.

A ground wiring layer 140 may extend from the inside of the base layer 110 to a side surface of the base layer 110. The ground wiring layer 140 may include, for example, a material similar to that of the ground plate layer 130.

In some embodiments, the ground wiring layer 140 may be electrically connected to the ground plate layer 130 through a ground via. Alternatively, in some embodiments, the ground wiring layer 140 may be electrically connected to a bottom connection pad 120, providing ground, of the plurality of bottom connection pads 120 through a conductive via and/or a wiring pattern provided in the base layer 110.

A wiring pattern and a conductive via for electrically connecting the plurality of bottom connection pads 120 to the plurality of top connection pads may be provided in the package base substrate 100. The wiring pattern and the conductive via may include, for example, metal such as copper.

The package body 200 may include a semiconductor chip 210 disposed on the package base substrate 100 and an encapsulation layer 250 that is on (e.g., that covers) the top of the package base substrate 100 and surrounds the semiconductor chip 210. The semiconductor chip 210 may include a semiconductor substrate. The semiconductor substrate may include, for example, silicon (Si). Alternatively, the semiconductor substrate may include a semiconductor element such as germanium (Ge) or a semiconductor compound such as silicon carbide (SiC), gallium arsenide (GaAs), indium arsenide (InAs), or indium phosphide (InP). The semiconductor substrate may include an active surface and an inactive surface opposite to the active surface. A semiconductor device including various kinds of a plurality of individual devices may be provided on the active surface of the semiconductor chip 210.

The semiconductor chip 210 may include a plurality of semiconductor chip pads disposed on the active surface. The plurality of semiconductor chip pads may be electrically connected to the plurality of top connections pads and may be electrically connected to the bottom connection pads 120 through the wiring pattern and/or the conductive via. In some embodiments, the semiconductor chip 210 may be electrically connected to the plurality of top connection pads through a bonding wire. In some embodiments, the semiconductor chip 210 may be electrically connected to the plurality of top connection pads through a chip connection terminal in a flip chip type.

In some embodiments, the semiconductor chip 210 may be a central processor/processing unit (CPU), a micro-processor unit (MPU), a graphics processor/processing unit (GPU), or an application processor (AP). In some embodiments, the semiconductor chip 210 may be a non-volatile memory semiconductor chip such as flash memory, phase-change random access memory (PRAM), magnetoresistive random access memory (MRAM), ferroelectric random access memory (FeRAM), or resistive random access memory (RRAM). The flash memory may be, for example, V-NAND flash memory. In some embodiments, the semiconductor chip 210 may be a volatile memory semiconductor chip such as dynamic random access memory (DRAM) or static random access memory (SRAM). In some embodiments, the semiconductor chip 210 may be a controller semiconductor chip for controlling the non-volatile memory semiconductor chip.

The package body 200 may include one semiconductor chip 210, but is not limited thereto. In some embodiments, the package body 200 may include a plurality of semiconductor chips 210. The AP may perform a function of the controller semiconductor chip, and in this case, the package body 200 may not include a separate controller semiconductor chip.

In some embodiments, the plurality of semiconductor chips 210 may be arranged in a horizontal direction on the package base substrate 100 and may be spaced apart from one another. In some embodiments, the plurality of semiconductor chips 210 may be stacked in a vertical direction on the package base substrate 100. In some embodiments, some of the plurality of semiconductor chips 210 may be arranged in the horizontal direction on the package base substrate 100 and may be spaced apart from one another, and other ones of the semiconductor chips 210 may be stacked in the vertical direction. In some embodiments, the package body 200 may be configured/provided as a PoP type.

The encapsulation layer 250 may include, for example, an under-fill material and/or an epoxy molding compound (EMC). In some embodiments, the encapsulation layer 250 may be on (e.g., may cover) a top of the semiconductor chip 210. In some embodiments, the encapsulation layer 250 may not cover at least a portion of the top of the semiconductor chip 210.

The electromagnetic shielding member 300 may be formed based on conformal shielding. The electromagnetic shielding member 300 may configure/provide one body with and may be on (e.g., may cover) a side surface of the package base substrate 100 and a side surface and a top of the package body 200. The electromagnetic shielding member 300 may be electrically connected to the ground plate layer 130. For example, the electromagnetic shielding member 300 may contact a side surface of the ground plate layer 130. Moreover, the electromagnetic shielding member 300 may be electrically connected to the ground wiring layer 140. For example, the electromagnetic shielding member 300 may contact a side surface of the ground wiring layer 140.

In some embodiments, the electromagnetic shielding member 300 may extend lower than a bottom of the ground plate layer 130. In some embodiments, the electromagnetic shielding member 300 may extend from the side surface of the ground plate layer 130 to a side surface of the bottom solder resist layer 150 and may be on (e.g., may cover) the side surface of the bottom solder resist layer 150. The electromagnetic shielding member 300 may not cover the bottom of the package base substrate 100. In some embodiments, a bottom of the bottom solder resist layer 150 and the bottom of the ground plate layer 130 may be disposed at the same level at an edge of the package base substrate 100.

The electromagnetic shielding member 300 may be formed by, for example, a physical vapor deposition (PVD) process. In some embodiments, the electromagnetic shielding member 300 may be formed by a sputtering process. For example, the electromagnetic shielding member 300 may include a metal material such as copper (Cu) or stainless steel. In some embodiments, the electromagnetic shielding member 300 may have a stacked structure where a stainless steel layer covers each of a top and a bottom of a copper layer. The electromagnetic shielding member 300 may be formed by, for example, a spray process. For example, the electromagnetic shielding member 300 may include a metal material such as silver. In some embodiments, the electromagnetic shielding member 300 may include a metal layer including silver and a carbon nano tube (CNT) layer disposed between the metal layer, the package base substrate 100, and the package body 200.

The electromagnetic shielding member 300 may shield an electromagnetic wave radiated from the package body 200 and an electromagnetic wave radiated from the side surface of the package base substrate 100. The ground plate layer 130 may shield an electromagnetic wave radiated from an outer portion of the ground fence GF on the bottom of the package base substrate 100. The ground fence GF may shield an electromagnetic wave radiated from an inner portion of the ground fence GF on the bottom of the package base substrate 100 and an electromagnetic wave EM radiated from the connection terminal 162. Therefore, the electromagnetic shielding member 300, the ground plate layer 130, and the ground fence GF may shield electromagnetic waves generated from the inside of the semiconductor package 1 and the connection terminal 162.

The ground fence GF may shield about 99% or more of the electromagnetic wave radiated from the inner portion of the ground fence GF on the bottom of the package base substrate 100 and the electromagnetic wave EM radiated from the connection terminal 162. The ground fence GF may be spaced apart from the real ball map RBM with the spacing region SR therebetween. A closest distance (i.e., a minimum width of the spacing region SR) between the ground fence GF and the real ball map RBM may have a value which is equal to or greater (e.g., higher) than an interval between two adjacent electromagnetic shielding terminals 164 of the plurality of electromagnetic shielding terminals 164 configuring/providing the ground fence GF. For example, if a maximum operating frequency of the semiconductor package 1 is 5.83 GHz (11.660 Gbps), the interval between two adjacent electromagnetic shielding terminals 164 of the plurality of electromagnetic shielding terminals 164 configuring/providing the ground fence GF may be about 1 millimeter (mm) or may have a value which is less than 1 mm.

Since the semiconductor package 1 according to some embodiments includes the electromagnetic shielding member 300 based on conformal shielding, the semiconductor package 1 may be miniaturized, and the ground plate layer 130 and the ground fence GF configured/provided by the plurality of electromagnetic shielding terminals 164 may shield an electromagnetic wave radiated through a space between the set board 10 and the package base substrate 100.

Therefore, reliability of products may be protected/prevented from being reduced by a problem/disorder such as electromagnetic noise or a malfunction which occurs in an electronic device including the semiconductor package 1 due to the semiconductor package 1.

FIGS. 1B to 1D are cross-sectional views illustrating a semiconductor package according to some embodiments. In descriptions made below with reference to FIGS. 1B to 1D, details which are the same as or similar to the details described above with reference to FIG. 1A may be omitted.

Referring to FIG. 1B, a semiconductor package la may include a package base substrate 100, a package body 200a mounted on the package base substrate 100, and an electromagnetic shielding member 300 on (e.g., covering) at least a portion of a surface of each of the package base substrate 100 and the package body 200a.

The package body 200a may include a first semiconductor chip 212 and a second semiconductor chip 214. In some embodiments, the first semiconductor chip 212 and the second semiconductor chip 214 may be arranged in a horizontal direction on the package base substrate 100 and may be spaced apart from each other. For example, the first semiconductor chip 212 may be a non-volatile memory semiconductor chip. In some embodiments, the first semiconductor chip 212 may be flash memory, flash memory where a plurality of semiconductor dies are stacked, or V-NAND flash memory. Moreover, the second semiconductor chip 214 may be, for example, a controller semiconductor chip for controlling a CPU, an MPU, a GPU, an AP, or a non-volatile memory semiconductor chip.

The package body 200a may include a NAND interface NIF, which electrically connects the first semiconductor chip 212 to the second semiconductor chip 214 to transfer a data signal between the first semiconductor chip 212 and the second semiconductor chip 214 or provides a control signal to the first semiconductor chip 212, and a host interface HIF which electrically connects the second semiconductor chip 214 to a bottom connection pad 120. The host interface HIF may provide an interface between the second semiconductor chip 214 and a host included in an electronic device including the semiconductor package la.

In some embodiments, the NAND interface NIF and the host interface HIF may each include at least one of a wiring pattern and/or a conductive via included in the package base substrate 100, a chip connection terminal attached on the first semiconductor chip 212 and/or the second semiconductor chip 214, and a bonding wire.

In some embodiments, at least some of power/ground and a clock signal that may be used (e.g., necessary) for an operation of the first semiconductor chip 212 may be provided to the first semiconductor chip 212 through the host interface HIF and the NAND interface NIF. In some embodiments, at least some of the power/ground and the clock signal used (e.g., necessary) for the operation of the first semiconductor chip 212 may be provided to the first semiconductor chip 212 through a separate conductive path connecting a portion of the bottom connection pad 120 to the first semiconductor chip 212 without accessing the NAND interface NIF.

The electromagnetic shielding member 300 may shield an electromagnetic wave radiated from the package body 200a and an electromagnetic wave radiated from a side surface of the package base substrate 100. The ground fence GF may be spaced apart from a real ball map RBM with a spacing region SR therebetween. A closest distance between the ground fence GF and the real ball map RBM may have a value which is equal to or greater (e.g., higher) than an interval between two adjacent electromagnetic shielding terminals 164 of a plurality of electromagnetic shielding terminals 164 configuring/providing the ground fence GF.

Referring to FIG. 1C, a semiconductor package 1b may include a package base substrate 100, a package body 200b mounted on the package base substrate 100, and an electromagnetic shielding member 300 on (e.g., covering) at least a portion of a surface of each of the package base substrate 100 and the package body 200b.

The package body 200b may include a first semiconductor chip 212 and a second semiconductor chip 214. In some embodiments, the first semiconductor chip 212 and the second semiconductor chip 214 may be disposed and stacked in a vertical direction on the package base substrate 100. For example, the first semiconductor chip 212 may be stacked on the second semiconductor chip 214. In some embodiments, the first semiconductor chip 212 and the second semiconductor chip 214 may each be configured/provided as a PoP type. For example, the first semiconductor chip 212 and the second semiconductor chip 214 may respectively be a top semiconductor package and a bottom semiconductor package which are each configured/provided as a PoP type. For example, the first semiconductor chip 212 may be a non-volatile memory semiconductor chip. In some embodiments, the first semiconductor chip 212 may be flash memory or V-NAND flash memory. For example, the second semiconductor chip 214 may be a controller semiconductor chip for controlling a CPU, an MPU, a GPU, an AP, or a non-volatile memory semiconductor chip.

The package body 200b may include a NAND interface NIF, which transfers a data signal between the first semiconductor chip 212 and the second semiconductor chip 214 or provides a control signal to the first semiconductor chip 212, and a host interface HIF which electrically connects the second semiconductor chip 214 to a bottom connection pad 120.

The electromagnetic shielding member 300 may shield an electromagnetic wave radiated from the package body 200b and an electromagnetic wave radiated from a side surface of the package base substrate 100. The ground fence GF may be spaced apart from a real ball map RBM with a spacing region SR therebetween. A closest distance between the ground fence GF and the real ball map RBM may have a value which is equal to or greater (e.g., higher) than an interval between two adjacent electromagnetic shielding terminals 164 of a plurality of electromagnetic shielding terminals 164 configuring/providing the ground fence GF.

Referring to FIG. 1D, a semiconductor package 1c may include a package base substrate 100, a package body 200c mounted on the package base substrate 100, and an electromagnetic shielding member 300 on (e.g., covering) at least a portion of a surface of each of the package base substrate 100 and the package body 200c.

The package body 200c may include a first semiconductor chip 212, a second semiconductor chip 214, and a third semiconductor chip 216. In some embodiments, some of the first semiconductor chip 212, the second semiconductor chip 214, and the third semiconductor chip 216 may be arranged in a horizontal direction on the package base substrate 100 and may be spaced apart from each other, and others of these semiconductor chips may be stacked in a vertical direction. In FIG. 1D, it is illustrated that the second semiconductor chip 214 and the third semiconductor chip 216 are arranged in the horizontal direction on the package base substrate 100 and are spaced apart from each other, and the first semiconductor chip 212, the second semiconductor chip 214, and the third semiconductor chip 216 are stacked in the vertical direction, but the present inventive concepts are not limited thereto.

In some embodiments, the first semiconductor chip 212 may be a top semiconductor package configured/provided as a PoP type, and the second semiconductor chip 214 and the third semiconductor chip 216 may each be a bottom semiconductor package configured/provided as a PoP type. For example, the first semiconductor chip 212 may be a non-volatile memory semiconductor chip. In some embodiments, the first semiconductor chip 212 may be flash memory or V-NAND flash memory. For example, the second semiconductor chip 214 may be a controller semiconductor chip for controlling a CPU, an MPU, a GPU, an AP, or a non-volatile memory semiconductor chip. In some embodiments, the third semiconductor chip 216 may be a non-volatile memory semiconductor chip such DRAM or SRAM. In some embodiments, the first and second semiconductor chips 212 and 214 and the third semiconductor chip 216 may independently operate. For example, a host included in an electronic device including the semiconductor package 1c may separately control each of the first and second semiconductor chips 212 and 214 and the third semiconductor chip 216.

The package body 200c may include a NAND interface NIF which transfers a data signal between the first semiconductor chip 212 and the second semiconductor chip 214 or provides a control signal to the first semiconductor chip 212, a host interface HIF which electrically connects the second semiconductor chip 214 to a bottom connection pad 120, and a DRAM interface DIF which electrically connects the third semiconductor chip 216 and the bottom connection pad 120.

In some embodiments, the DRAM interface DIF may include a wiring pattern and/or a conductive via included in the package base substrate 100, a chip connection terminal attached on the third semiconductor chip 216, and a bonding wire which electrically connects the third semiconductor chip 216 to the package base substrate 100. The DRAM interface DIF may provide an interface between the second semiconductor chip 214 and the host included in the electronic device including the semiconductor package 1c.

The electromagnetic shielding member 300 may shield an electromagnetic wave radiated from the package body 200c and an electromagnetic wave radiated from a side surface of the package base substrate 100. A ground fence GF may be spaced apart from a real ball map RBM with a spacing region SR therebetween. A closest distance between the ground fence GF and the real ball map RBM may have a value which is equal to or greater (e.g., higher) than an interval between two adjacent electromagnetic shielding terminals 164 of a plurality of electromagnetic shielding terminals 164 configuring/providing the ground fence GF.

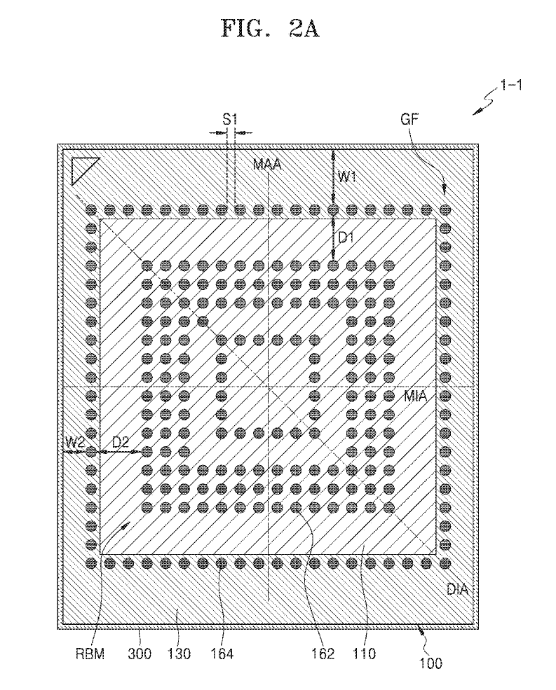

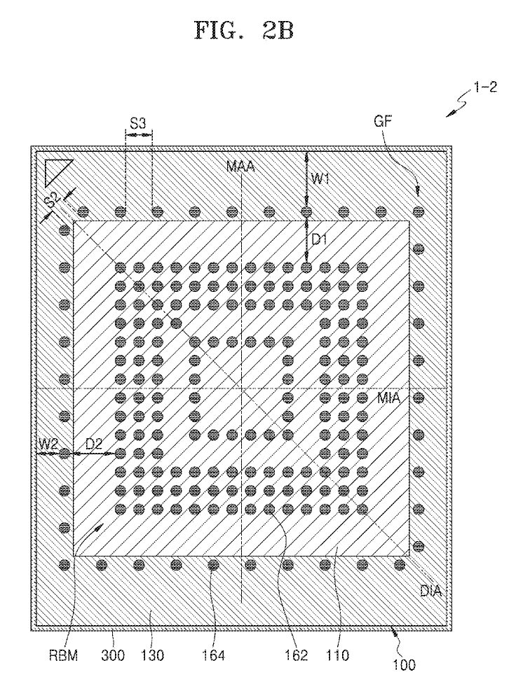

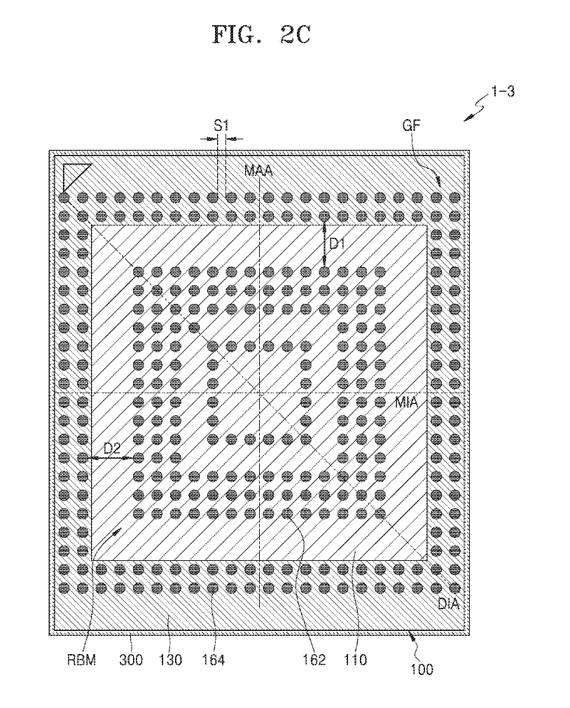

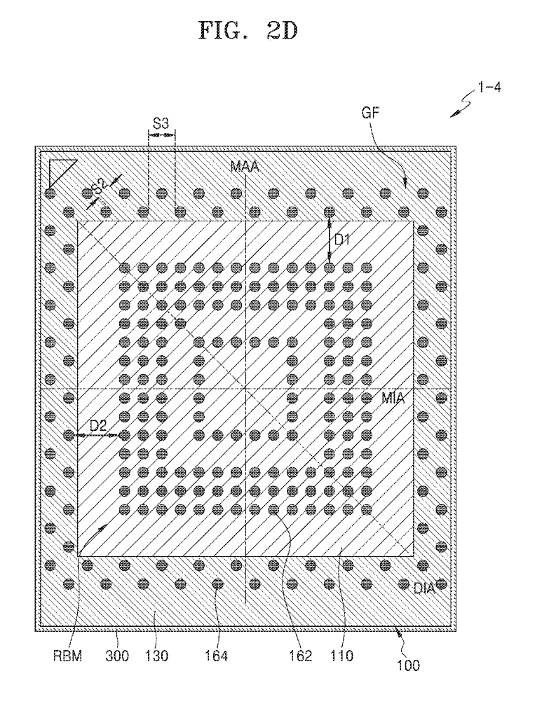

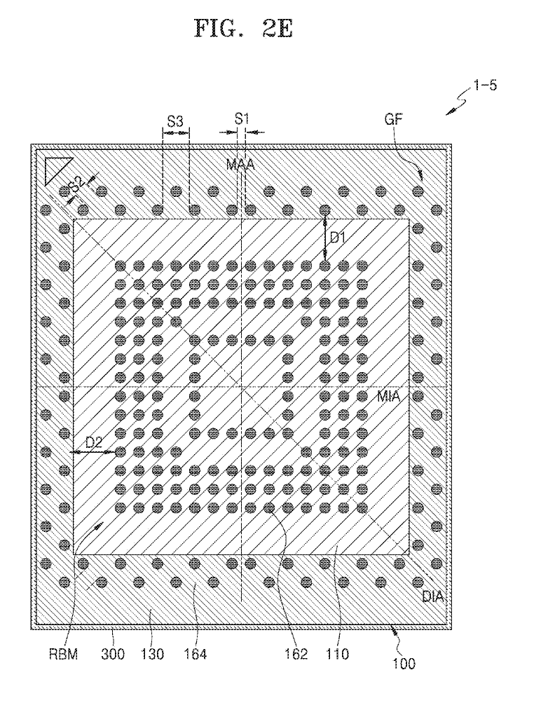

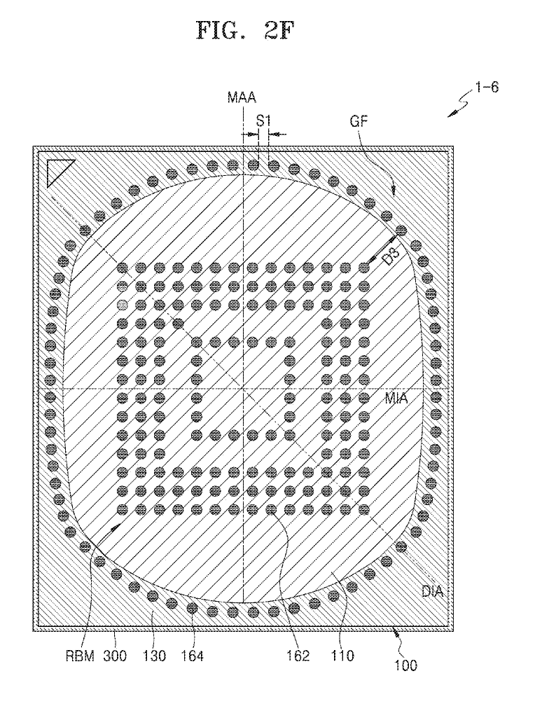

FIGS. 2A to 2F are bottom views illustrating a main part of a semiconductor package according to some embodiments. Each of a plurality of semiconductor packages 1-1 to 1-6 described below with reference to FIGS. 2A to 2F may be one of the semiconductor packages 1 and 1a to 1c described above with reference to FIGS. 1A to 1D. Therefore, in descriptions made below with reference to FIGS. 2A to 2F, details which are the same as or similar to the details described above with reference to FIGS. 1A to 1D may be omitted. Also, in FIGS. 2A to 2F, for convenience of description and illustration, the bottom solder resist layer 150 described above with reference to FIGS. 1A to 1D is omitted and thus not illustrated.

Referring to FIG. 2A along with FIGS. 1A to 1D, the semiconductor package 1-1 may include a package base substrate 100, a package body (one of 200 and 200a to 200c) mounted on the package base substrate 100, and an electromagnetic shielding member 300 on (e.g., covering) at least a portion of a surface of each of the package base substrate 100 and the package body (one of 200 and 200a to 200c).

The semiconductor package 1-1 may include a bridge region BR, a fence region FR surrounding the bridge region BR, a spacing region SR between the bridge region BR and the fence region FR, and an edge region ER between an edge of the semiconductor package 1-1 and the fence region FR.

The package base substrate 100 may include at least one base layer 110, a plurality of bottom connection pads 120 disposed on a bottom of the package base substrate 100, a plurality of connection terminals 162 respectively attached on the plurality of bottom connection pads 120, a ground plate layer 130 which contacts an edge of a bottom of the base layer 110 and extends to the inside of the bottom of the base layer 110, and a plurality of electromagnetic shielding terminals 164 attached on the ground plate layer 130.

The ground plate layer 130 may contact the electromagnetic shielding terminals 164 and may be electrically connected to the electromagnetic shielding terminals 164. The ground plate layer 130 may surround the bridge region BR along an edge of the bottom of the base layer 110. The ground plate layer 130 may have a polygonal (e.g., quadrilateral/tetragonal) ring shape and may completely surround the bridge region BR.

The plurality of connection terminals 162 may configure/provide a real ball map RBM that may be used (e.g., necessary) for an operation of the semiconductor package 1-1. The plurality of electromagnetic shielding terminals 164 may be spaced apart from one another and may be disposed to surround the real ball map RBM configured/provided by the plurality of connection terminals 162. The plurality of electromagnetic shielding terminals 164 may configure/provide a ground fence GF.

In some embodiments, the plurality of electromagnetic shielding terminals 164 may be spaced apart from one another by a first spacing S1 and may be disposed to surround the real ball map RBM configured/provided by the plurality of connection terminals 162. The ground fence GF configured/provided by the plurality of electromagnetic shielding terminals 164 may have a polygonal (e.g., quadrilateral/tetragonal) shape and may surround the real ball map RBM configured/provided by the plurality of connection terminals 162.

A distance (i.e., a width of the spacing region SR) between the real ball map RBM configured/provided by the plurality of connection terminals 162 and the ground fence GF configured/provided by the plurality of electromagnetic shielding terminals 164 may include a first distance D1 and a second distance D2. For example, the first distance D1 may be a shortest distance between the real ball map RBM and the ground fence GF in a long-axis direction, and the second distance D2 may be a shortest distance between the real ball map RBM and the ground fence GF in a short-axis direction. Here, in a case where the semiconductor package 1-1 (i.e., the package base substrate 100) has a rectangular-shaped horizontal cross-sectional surface form, the long-axis direction and the short-axis direction may be a long-axis direction and a short-axis direction of the rectangular-shaped horizontal cross-sectional surface.

The first distance D1 and the second distance D2 may each have a value which is equal to or greater (e.g., higher) than the first spacing S1. In some embodiments, the first distance D1 and the second distance D2 may each have a value which is greater than the first spacing S1. That is, a minimum width of the spacing region SR may have a value which is equal to or greater than the first spacing S1. In some embodiments, the first distance D1 and the second distance D2 may have the same value.

A width (i.e., a width of the edge region ER) between the ground fence GF configured/provided by the plurality of electromagnetic shielding terminals 164 and an edge of the package base substrate 100 may include a first width W1 and a second width W2. For example, the first width W1 may be a width between the edge of the package base substrate 100 and the ground fence GF in the long-axis direction, and the second width W2 may be a width between the edge of the package base substrate 100 and the ground fence GF in the short-axis direction. The first width W1 may have a value which is greater than the first distance D1, and the second width W2 may have a value which is less than the second distance D2. That is, a ratio of the width of the edge region ER to a width of the spacing region SR in the long-axis direction may be greater than one, and a ratio of the width of the edge region ER to the width of the spacing region SR in the short-axis direction may be less than one.

As described above, the ratio of the width of the edge region ER to the width of the spacing region SR in the long-axis direction may differ from the ratio of the width of the edge region ER to the width of the spacing region SR in the short-axis direction, and thus, bending of the semiconductor package 1-1 may be effectively controlled.

The plurality of electromagnetic shielding terminals 164 configuring/providing the ground fence GF may be disposed symmetric about a center line MAA of the ground fence GF which extends along the long-axis direction. The plurality of electromagnetic shielding terminals 164 configuring/providing the ground fence GF may be disposed symmetric about a center line MIA of the ground fence GF which extends along the short-axis direction. The plurality of electromagnetic shielding terminals 164 configuring/providing the ground fence GF may be disposed symmetric about a center line DIA of the ground fence GF which extends along a diagonal direction of the ground fence GF. The center line MAA of the ground fence GF extending in the long-axis direction, the center line MIA of the ground fence GF extending in the short-axis direction, and the center line DIA of the ground fence GF extending in the diagonal direction may be referred to as a first center line MAA, a second center line MIA, and a third center line DIA. Therefore, the plurality of electromagnetic shielding terminals 164 configuring/providing the ground fence GF may be disposed symmetric about each of the first center line MAA, the second center line MIA, and the third center line DIA.

Referring to FIG. 2B along with FIGS. 1A to 1D, the semiconductor package 1-2 may include a package base substrate 100, a package body (one of 200 and 200a to 200c) mounted on the package base substrate 100, and an electromagnetic shielding member 300 on (e.g., covering) at least a portion of a surface of each of the package base substrate 100 and the package body (one of 200 and 200a to 200c).

The semiconductor package 1-2 may include a bridge region BR, a fence region FR surrounding the bridge region BR, a spacing region SR between the bridge region BR and the fence region FR, and an edge region ER between an edge of the semiconductor package 1-2 and the fence region FR.

A plurality of connection terminals 162 may configure/provide a real ball map RBM that may be used (e.g., necessary) for an operation of the semiconductor package 1-2. A plurality of electromagnetic shielding terminals 164 may be spaced apart from one another and may be disposed to surround the real ball map RBM configured/provided by the plurality of connection terminals 162. The plurality of electromagnetic shielding terminals 164 may configure/provide (e.g., define) a ground fence GF.

In some embodiments, some of the plurality of electromagnetic shielding terminals 164 may be spaced apart from one another by a second spacing S2, and others of the electromagnetic shielding terminals 164 may be spaced apart from one another by a third spacing S3 and may be disposed to surround the real ball map RBM configured/provided by the plurality of connection terminals 162. The second spacing S2 may have a value which is less than the third spacing S3. In some embodiments, some of the plurality of electromagnetic shielding terminals 164 disposed in a vertex portion of the ground fence GF may be spaced apart from one another by the second spacing S2, and others of the electromagnetic shielding terminals 164 may be spaced apart from one another by the third spacing S3.

A distance between the real ball map RBM configured/provided by the plurality of connection terminals 162 and the ground fence GF configured/provided by the plurality of electromagnetic shielding terminals 164 may include a first distance D1 and a second distance D2. The first distance D1 and the second distance D2 may each have a value which is equal to or greater than the second spacing S2 and the third spacing S3. In some embodiments, the first distance D1 and the second distance D2 may each have a value which is greater than the second spacing S2 and the third spacing S3. In some embodiments, the first distance D1 and the second distance D2 may have the same value.

The first distance D1 and the second distance D2 may each have a value which is equal to or greater than any one of the spacings S1, S2, and S3. In some embodiments, the first distance D1 and the second distance D2 may each have a value which is greater than any one of the spacings S1, S2, and S3. That is, a minimum width of the spacing region SR may have a value which is equal to or greater than any one of the spacings S1, S2, and S3. In some embodiments, the first distance D1 and the second distance D2 may have the same value.

The plurality of electromagnetic shielding terminals 164 configuring/providing the ground fence GF may be disposed asymmetric about each of a first center line MAA and a second center line MIA. The plurality of electromagnetic shielding terminals 164 configuring/providing the ground fence GF may be disposed symmetric about a third center line DIA.

Referring to FIG. 2C along with FIGS. 1A to 1D, the semiconductor package 1-3 may include a package base substrate 100, a package body (one of 200 and 200a to 200c) mounted on the package base substrate 100, and an electromagnetic shielding member 300 on (e.g., covering) at least a portion of a surface of each of the package base substrate 100 and the package body (one of 200 and 200a to 200c).

The semiconductor package 1-3 may include a bridge region BR, a fence region FR surrounding the bridge region BR, a spacing region SR between the bridge region BR and the fence region FR, and an edge region ER between an edge of the semiconductor package 1-3 and the fence region FR.

A plurality of connection terminals 162 may configure/provide a real ball map RBM that may be used (e.g., necessary) for an operation of the semiconductor package 1-3. A plurality of electromagnetic shielding terminals 164 may be spaced apart from one another and may be disposed to surround the real ball map RBM configured/provided by the plurality of connection terminals 162. The plurality of electromagnetic shielding terminals 164 may configure/provide a ground fence GF.

In some embodiments, the plurality of electromagnetic shielding terminals 164 may be spaced apart from one another by a first spacing S1 and may be disposed to surround the real ball map RBM configured/provided by the plurality of connection terminals 162. The plurality of electromagnetic shielding terminals 164 may be disposed in two rows along a periphery of the real ball map RBM configured/provided by the plurality of connection terminals 162.

A distance between the real ball map RBM configured/provided by the plurality of connection terminals 162 and the ground fence GF configured/provided by the plurality of electromagnetic shielding terminals 164 may include a first distance D1 and a second distance D2. The first distance D1 and the second distance D2 may each have a value which is equal to or greater than the first spacing S1. In some embodiments, the first distance D1 and the second distance D2 may each have a value which is greater than the first spacing S1. In some embodiments, the first distance D1 and the second distance D2 may have the same value.

The plurality of electromagnetic shielding terminals 164 configuring/providing the ground fence GF may be disposed symmetric about each of a first center line MAA, a second center line MIA, and a third center line DIA.

Referring to FIG. 2D along with FIGS. 1A to 1D, the semiconductor package 1-4 may include a package base substrate 100, a package body (one of 200 and 200a to 200c) mounted on the package base substrate 100, and an electromagnetic shielding member 300 on (e.g., covering) at least a portion of a surface of each of the package base substrate 100 and the package body (one of 200 and 200a to 200c).

The semiconductor package 1-4 may include a bridge region BR, a fence region FR surrounding the bridge region BR, a spacing region SR between the bridge region BR and the fence region FR, and an edge region ER between an edge of the semiconductor package 1-4 and the fence region FR.

A plurality of connection terminals 162 may configure/provide a real ball map RBM that may be used (e.g., necessary) for an operation of the semiconductor package 1-4. A plurality of electromagnetic shielding terminals 164 may be spaced apart from one another and may be disposed to surround the real ball map RBM configured/provided by the plurality of connection terminals 162. The plurality of electromagnetic shielding terminals 164 may configure/provide a ground fence GF.

In some embodiments, the plurality of electromagnetic shielding terminals 164 may be spaced apart from one another by a second spacing S2 and may be disposed in zigzags (e.g., a zigzag pattern) along a periphery of the real ball map RBM configured/provided by the plurality of connection terminals 162. Some electromagnetic shielding terminals 164, which are disposed in a vertex portion of the ground fence GF and configure/provide an inner row surrounding the real ball map RBM configured/provided by the plurality of connection terminals 162, of the plurality of electromagnetic shielding terminals 164 may be spaced apart from one another by the second spacing S2, and others of the electromagnetic shielding terminals 164 may be spaced apart from one another by a third spacing S3. Likewise, some electromagnetic shielding terminals 164, which are disposed in the vertex portion of the ground fence GF and configure/provide an outer row surrounding the real ball map RBM configured/provided by the plurality of connection terminals 162, of the plurality of electromagnetic shielding terminals 164 may be spaced apart from one another by the second spacing S2, and others of the electromagnetic shielding terminals 164 may be spaced apart from one another by a third spacing S3.

A distance between the real ball map RBM configured/provided by the plurality of connection terminals 162 and the ground fence GF configured/provided by the plurality of electromagnetic shielding terminals 164 may include a first distance D1 and a second distance D2. The first distance D1 and the second distance D2 may each have a value which is equal to or greater than the second spacing S2. In some embodiments, the first distance D1 and the second distance D2 may each have a value which is greater than the second spacing S2. The first distance D1 and the second distance D2 may each have a value which is equal to or greater than the third spacing S3. In some embodiments, the first distance D1 and the second distance D2 may each have a value which is greater than the third spacing S3. In some embodiments, the first distance D1 and the second distance D2 may have the same value.

The plurality of electromagnetic shielding terminals 164 configuring/providing the ground fence GF may be disposed asymmetric about each of a first center line MAA and a second center line MIA. The plurality of electromagnetic shielding terminals 164 configuring/providing the ground fence GF may be disposed symmetric about a third center line DIA.

Referring to FIG. 2E along with FIGS. 1A to 1D, the semiconductor package 1-5 may include a package base substrate 100, a package body (one of 200 and 200a to 200c) mounted on the package base substrate 100, and an electromagnetic shielding member 300 on (e.g., covering) at least a portion of a surface of each of the package base substrate 100 and the package body (one of 200 and 200a to 200c).

The semiconductor package 1-5 may include a bridge region BR, a fence region FR surrounding the bridge region BR, a spacing region SR between the bridge region BR and the fence region FR, and an edge region ER between an edge of the semiconductor package 1-5 and the fence region FR.

A plurality of connection terminals 162 may configure/provide a real ball map RBM that may be used (e.g., necessary) for an operation of the semiconductor package 1-5. A plurality of electromagnetic shielding terminals 164 may be spaced apart from one another and may be disposed to surround the real ball map RBM configured/provided by the plurality of connection terminals 162. The plurality of electromagnetic shielding terminals 164 may configure/provide a ground fence GF.

In some embodiments, some of the plurality of electromagnetic shielding terminals 164 may be spaced apart from one another by a first spacing S1, and others of the electromagnetic shielding terminals 164 may be spaced apart from one another by a second spacing S2 and may be disposed in zigzags to surround the real ball map RBM configured/provided by the plurality of connection terminals 162. Some electromagnetic shielding terminals 164, which are adjacent to the first center line MAA and configure/provide an inner row surrounding the real ball map RBM configured/provided by the plurality of connection terminals 162, of the plurality of electromagnetic shielding terminals 164 may be spaced apart from one another by the first spacing S1, some other electromagnetic shielding terminals 164 disposed in a vertex portion of the ground fence GF may be spaced apart from one another by the second spacing S2, and others of the electromagnetic shielding terminals 164 may be spaced apart from one another by a third spacing S3.

In some embodiments, some electromagnetic shielding terminals 164, which may configure/provide an outer row surrounding the real ball map RBM configured/provided by the plurality of connection terminals 162, of the plurality of electromagnetic shielding terminals 164 may be omitted and thus not disposed.

A distance between the real ball map RBM configured/provided by the plurality of connection terminals 162 and the ground fence GF configured/provided by the plurality of electromagnetic shielding terminals 164 may include a first distance D1 and a second distance D2. The first distance D1 and the second distance D2 may each have a value which is equal to or greater than the first spacing S1, the second spacing S2, and the third spacing S3. In some embodiments, the first distance D1 and the second distance D2 may each have a value which is greater than the first spacing S1, the second spacing S2, and the third spacing S3. The first distance D1 and the second distance D2 may each have a value which is equal to or greater than the third spacing S3. In some embodiments, the first distance D1 and the second distance D2 may have the same value.

The plurality of electromagnetic shielding terminals 164 configuring/providing the ground fence GF may be disposed symmetric about each of a first center line MAA, a second center line MIA, and a third center line DIA.

Referring to FIG. 2F along with FIGS. 1A to 1D, the semiconductor package 1-6 may include a package base substrate 100, a package body (one of 200 and 200a to 200c) mounted on the package base substrate 100, and an electromagnetic shielding member 300 on (e.g., covering) at least a portion of a surface of each of the package base substrate 100 and the package body (one of 200 and 200a to 200c).

The semiconductor package 1-6 may include a bridge region BR, a fence region FR surrounding the bridge region BR, a spacing region SR between the bridge region BR and the fence region FR, and an edge region ER between an edge of the semiconductor package 1-6 and the fence region FR.

A plurality of connection terminals 162 may configure/provide a real ball map RBM that may be used (e.g., necessary) for an operation of the semiconductor package 1-6. A plurality of electromagnetic shielding terminals 164 may be spaced apart from one another and may be disposed to surround the real ball map RBM configured/provided by the plurality of connection terminals 162. The plurality of electromagnetic shielding terminals 164 may configure/provide a ground fence GF.

In some embodiments, the plurality of electromagnetic shielding terminals 164 may be spaced apart from one another by a first spacing S1 and may be disposed to surround the real ball map RBM configured/provided by the plurality of connection terminals 162. The ground fence GF configured/provided by the plurality of electromagnetic shielding terminals 164 may have a circular/loop shape and may surround the real ball map RBM configured/provided by the plurality of connection terminals 162.

A shortest distance between the real ball map RBM configured/provided by the plurality of connection terminals 162 and the ground fence GF configured/provided by the plurality of electromagnetic shielding terminals 164 may be a third distance D3. The third distance D3 may have a value which is equal to or greater than the first spacing S1. In some embodiments, the third distance D3 may have a value which is greater than the first spacing S1.

The plurality of electromagnetic shielding terminals 164 configuring/providing the ground fence GF may be disposed symmetric about each of a first center line MAA, a second center line MIA, and a third center line DIA.

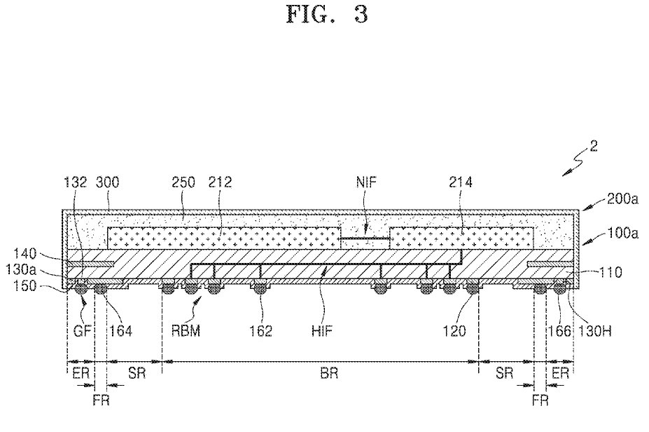

FIG. 3 is a cross-sectional view illustrating a semiconductor package 2 according to some embodiments. In descriptions made below with reference to FIG. 3, details which are the same as or similar to the details described above (e.g., with reference to FIG. 1B) may be omitted.

Referring to FIG. 3, the semiconductor package 2 may include a package base substrate 100a, a package body 200a mounted on the package base substrate 100a, and an electromagnetic shielding member 300 on (e.g., covering) at least a portion of a surface of each of the package base substrate 100a and the package body 200a.

A ground plate layer 130a may be disposed on a bottom of a base layer 110. The ground plate layer 130a may contact an edge of the bottom of the base layer 110 and may extend to the inside of the bottom of the base layer 110, and a plurality of electromagnetic shielding terminals 164 may be attached on the ground plate layer 130a. The ground plate layer 130a may surround the bridge region BR along the edge of the bottom of the base layer 110. The ground plate layer 130a may be covered by a bottom solder resist layer 150. The bottom solder resist layer 150 on a bottom of the ground plate layer 130a may not cover a portion of the fence region FR. An electromagnetic shielding terminal 164 may be attached on a portion of the ground plate layer 130a uncovered by the bottom solder resist layer 150.

The ground plate layer 130a may include a through hole 130H which passes through the ground plate layer 130a. In some embodiments, a dummy pad 132 may be disposed in the through hole 130H. The dummy pad 132 may include the same material as that of the ground plate layer 130a.

A dummy terminal 166 may be attached on the dummy pad 132. That is, the dummy terminal 166 may be disposed on the bottom of the base layer 110 at a position corresponding to the through hole 130H. The dummy terminal 166 may be disposed adjacent to a vertex portion of the bottom of the base layer 110, thereby protecting/preventing the semiconductor package 2 from being bent in a diagonal direction of the semiconductor package 2. The dummy terminal 166 may be, for example, a solder ball or a bump. In some embodiments, the dummy pad 132 may be omitted, and the dummy terminal 166 may be attached on the bottom of the base layer 110. The dummy terminal 166 may be electrically insulated from the ground plate layer 130a. The dummy terminal 166 may be electrically insulated from a NAND interface NIF and a host interface HIF.

The dummy terminal 166 may include the same material as that of each of the electromagnetic shielding terminal 164 and the connection terminal 162. In some embodiments, the dummy terminal 166 may have a shape which is substantially the same as that of each of the electromagnetic shielding terminal 164 and the connection terminal 162. For example, the dummy terminal 166 may be formed by the same manufacturing process as the electromagnetic shielding terminal 164 and the connection terminal 162.

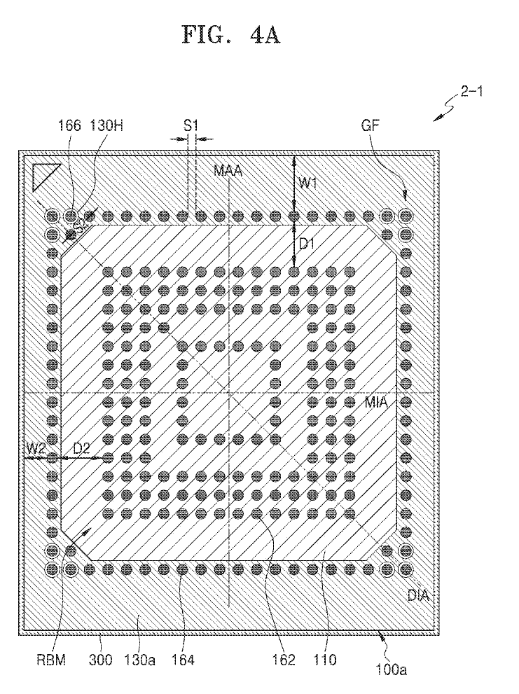

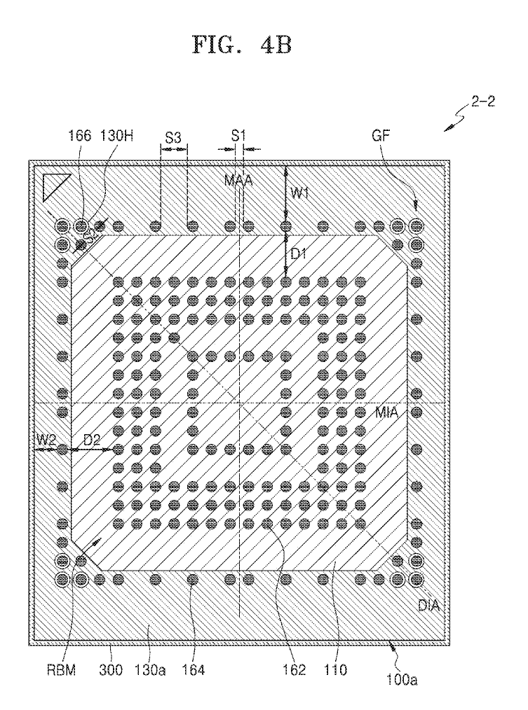

FIGS. 4A and 4B are bottom views illustrating a main part of a semiconductor package according to some embodiments. In FIGS. 4A and 4B, for convenience of description and illustration, the bottom solder resist layer 150 described above with reference to FIG. 3 is omitted and thus not illustrated.

Referring to FIG. 4A, a semiconductor package 2-1 may include a plurality of electromagnetic shielding terminals 164 configuring/providing a ground fence GF. The plurality of electromagnetic shielding terminals 164 spaced apart from one another may be disposed to surround a real ball map RBM configured/provided by a plurality of connection terminals 162. The ground fence GF including the plurality of electromagnetic shielding terminals 164 may have a polygonal (e.g., quadrilateral/tetragonal) shape of which four vertexes (i.e., vertices) are cut, and may surround the real ball map RBM including the plurality of connection terminals 162.

In some embodiments, some of the plurality of electromagnetic shielding terminals 164 may be spaced apart from one another by a first spacing S1, and others of the electromagnetic shielding terminals 164 may be spaced apart from one another by a second spacing S2. The first spacing S1 may have a value which is less than the second spacing S2. In some embodiments, some of electromagnetic shielding terminals 164 disposed adjacent to a cut-vertex portion of the ground fence GF may be spaced apart from one another by the second spacing S2, and others of the plurality of electromagnetic shielding terminals 164 may be spaced apart from one another by the first spacing S1.

The dummy terminal 166 and the through hole 130H passing through the ground plate layer 130a may be disposed in a cut-vertex portion of the ground fence GF having a polygonal (e.g., quadrilateral/tetragonal) shape of which four vertexes are cut.

The plurality of electromagnetic shielding terminals 164 configuring/providing the ground fence GF and the dummy terminal 166 may be disposed symmetric about each of a first center line MAA, a second center line MIA, and a third center line DIA.

Except that the dummy terminal 166 is disposed in a cut-vertex portion, the ground fence GF illustrated in FIG. 4A has a structure similar to that of the ground fence GF illustrated in FIG. 2A, but is not limited thereto. For example, the ground fence GF illustrated in FIG. 4A may have a structure similar to that of the ground fence GF illustrated in each of FIGS. 2B to 2F.

Referring to FIG. 4B, the semiconductor package 2-2 may include a plurality of electromagnetic shielding terminals 164 configuring/providing a ground fence GF. The plurality of electromagnetic shielding terminals 164 spaced apart from one another may be disposed to surround a real ball map RBM configured/provided by a plurality of connection terminals 162. The ground fence GF including the plurality of electromagnetic shielding terminals 164 may have a polygonal (e.g., quadrilateral/tetragonal) shape of which four vertexes are cut, and may surround the real ball map RBM including the plurality of connection terminals 162.

In some embodiments, some of the plurality of electromagnetic shielding terminals 164 may be spaced apart from one another by a first spacing S1, some others of the electromagnetic shielding terminals 164 may be spaced apart from one another by a second spacing S2, and still others of the electromagnetic shielding terminals 164 may be spaced apart from one another by a third spacing S3 and may be disposed to surround the real ball map RBM including the plurality of connection terminals 162. The first spacing S1 may have a value which is less than the second spacing S2, and the second spacing S2 may have a value which is less than the third spacing S3. In some embodiments, some electromagnetic shielding terminals 164, which are adjacent to a first center line MAA, of the plurality of electromagnetic shielding terminals 164 may be spaced apart from one another by the first spacing S1, some others of the electromagnetic shielding terminals 164 disposed adjacent to a cut-vertex portion of the ground fence GF may be spaced apart from one another by the second spacing S2, and still others of the electromagnetic shielding terminals 164 may be spaced apart from one another by the third spacing S3.

The dummy terminal 166 and the through hole 130H passing through the ground plate layer 130a may be disposed in a cut-vertex portion of the ground fence GF having a polygonal (e.g., quadrilateral/tetragonal) shape of which four vertexes are cut.

The plurality of electromagnetic shielding terminals 164 configuring/providing the ground fence GF and the dummy terminal 166 may be disposed symmetric about each of a first center line MAA, a second center line MIA, and a third center line DIA.

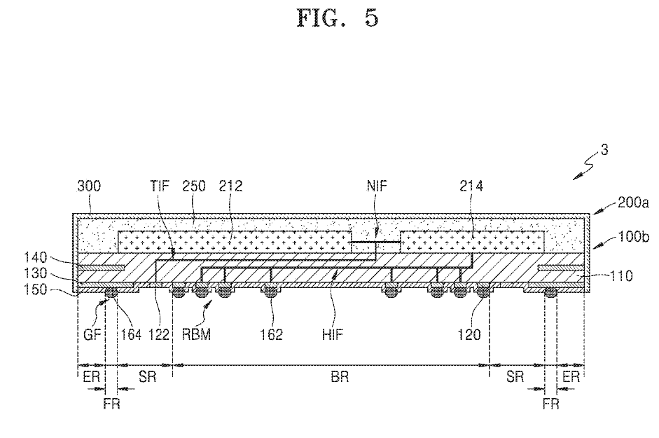

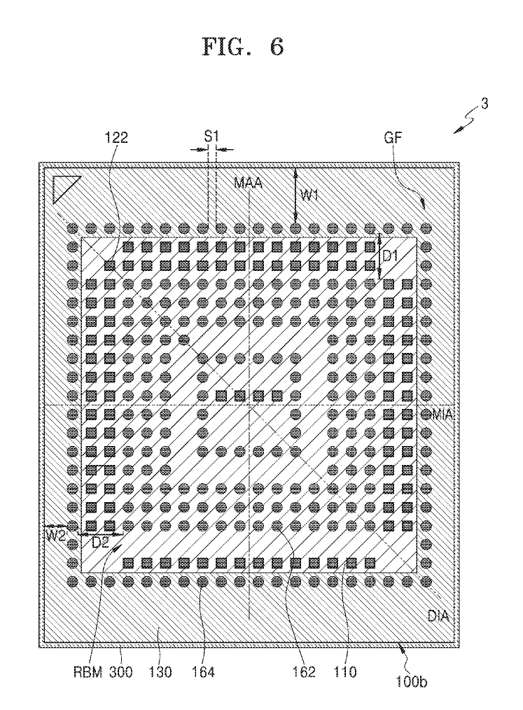

FIG. 5 is a cross-sectional view illustrating a semiconductor package 3 according to some embodiments, and FIG. 6 is a bottom view illustrating a main part of the semiconductor package 3 according to some embodiments. In descriptions made below with reference to FIGS. 5 and 6, details which are the same as or similar to the details described above (e.g., with reference to FIGS. 1B and 2A) may be omitted.

Referring to FIG. 5, the semiconductor package 3 may include a package base substrate 100b, a package body 200a mounted on the package base substrate 100b, and an electromagnetic shielding member 300 on (e.g., covering) at least a portion of a surface of each of the package base substrate 100b and the package body 200a.

A plurality of top connection pads, a plurality of bottom connection pads 120, and a plurality of test pads 122 may be disposed on a top and a bottom of the package base substrate 100b. The plurality of bottom connection pads 120 and the plurality of test pads 122 may be exposed at the bottom of the package base substrate 100b without being covered by a bottom solder resist layer 150.

The plurality of test pads 122 may be electrically connected to a NAND interface NIF. The plurality of test pads 122 may be electrically connected to a NAND interface NIF through a test interface TIF. In some embodiments, the text interface TIF may be configured/provided with a wiring pattern and/or a conductive via included in the package base substrate 100b.

The plurality of test pads 122 may be disposed in at least one of a spacing region SR and a bridge region BR. Therefore, the plurality of test pads 122 may be surrounded by a ground fence GF. Therefore, a plurality of electromagnetic shielding terminals 164 may be spaced apart from one another and may be disposed to surround the plurality of test pads 122 and a real ball map RBM configured/provided by a plurality of connection terminals 162.

The ground fence GF may shield an electromagnetic wave radiated from the bottom of the package base substrate 100b disposed on an inner side of the ground fence GF, an electromagnetic wave radiated from each of the connection terminals 162, and an electromagnetic wave radiated from each of the test pads 122.

The ground fence GF illustrated in FIGS. 5 and 6 may have a structure similar to that of the ground fence GF illustrated in FIG. 2A, but is not limited thereto. For example, the ground fence GF illustrated in FIGS. 5 and 6 may have a structure similar to that of the ground fence GF illustrated in FIGS. 2B to 2F, and the ground fence GF illustrated in FIGS. 5 and 6 may have a structure similar to that of the ground fence GF illustrated in FIGS. 4A and 4B.

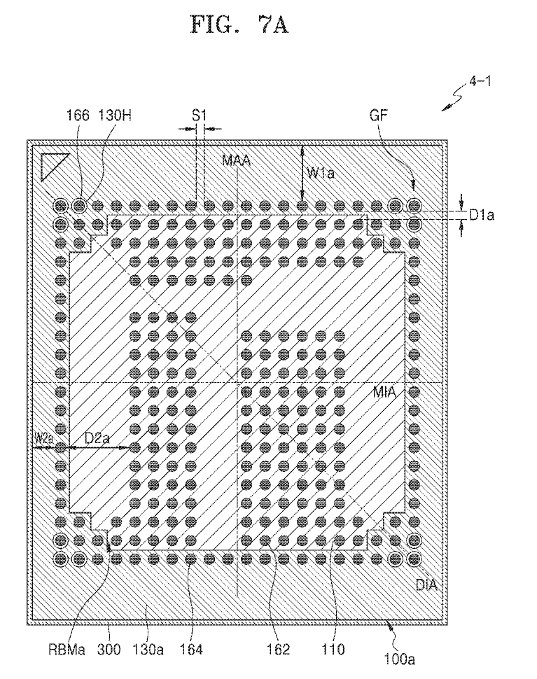

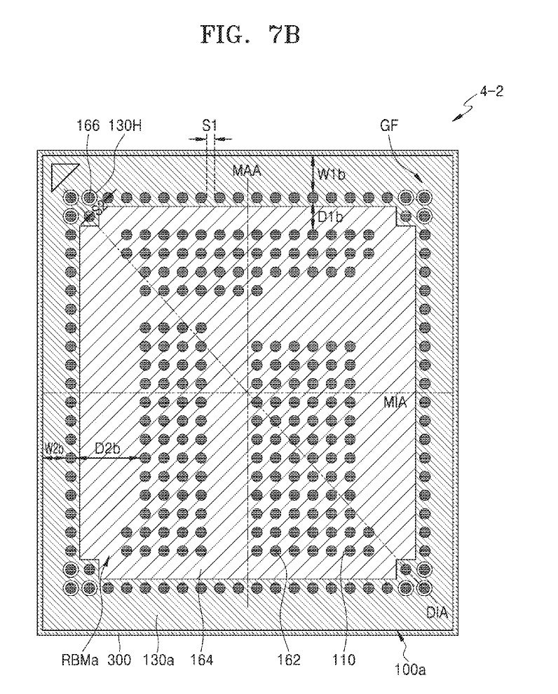

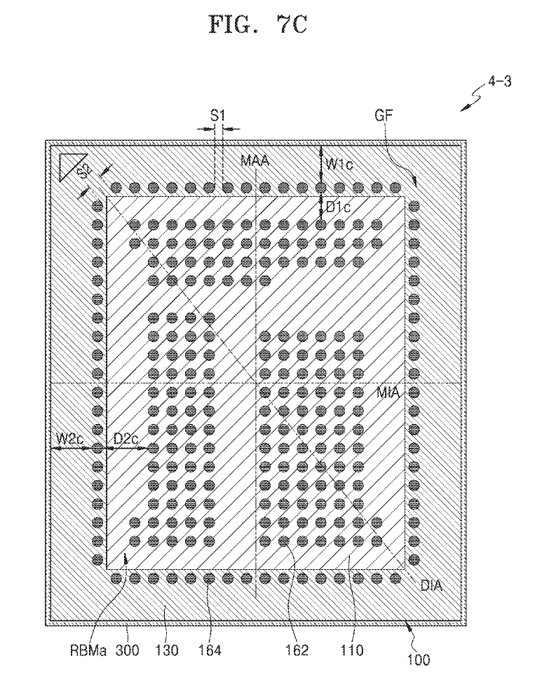

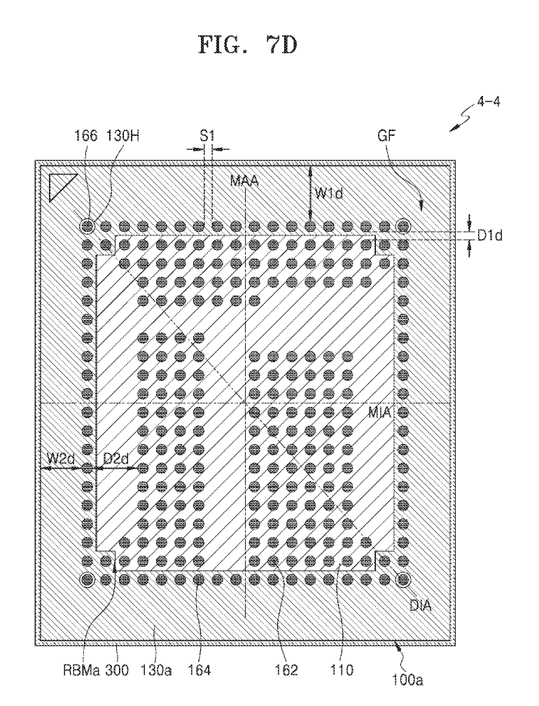

FIGS. 7A to 7D are bottom views illustrating a main part of a semiconductor package according to some embodiments. In descriptions made below with reference to FIGS. 7A to 7D, details which are the same as or similar to the details described above with reference to FIGS. 1A and 6 may be omitted.

Referring to FIG. 7A, a semiconductor package 4-1 may include a plurality of electromagnetic shielding terminals 164 configuring/providing a ground fence GF. The plurality of electromagnetic shielding terminals 164 spaced apart from one another may be disposed to surround a real ball map RBMa configured/provided by a plurality of connection terminals 162. In some embodiments, the number of connection terminals 162 configuring/providing the real ball map RBMa may be 221, but is not limited thereto. For example, in some embodiments, the number of the connection terminals 162 configuring/providing the real ball map RBMa may be 254.

The ground fence GF including the plurality of electromagnetic shielding terminals 164 may have a polygonal (e.g., quadrilateral/tetragonal) shape of which four vertexes are cut, and may surround the real ball map RBMa including the plurality of connection terminals 162.

The ground fence GF including the plurality of electromagnetic shielding terminals 164 may have a polygonal (e.g., quadrilateral/tetragonal) shape of which four vertexes are cut, and may surround the real ball map RBMa including the plurality of connection terminals 162. In some embodiments, the plurality of electromagnetic shielding terminals 164 may be spaced apart from one another by a first spacing S1 and may be disposed to surround the real ball map RBMa configured/provided by the plurality of connection terminals 162.

A distance between the real ball map RBMa configured/provided by the plurality of connection terminals 162 and the ground fence GF configured/provided by the plurality of electromagnetic shielding terminals 164 may include a first distance D1a and a second distance D2a. For example, the first distance D1a may be a distance between the real ball map RBMa and the ground fence GF in a long-axis direction, and the second distance D2a may be a distance between the real ball map RBMa and the ground fence GF in a short-axis direction.

The first distance D1a and the second distance D2a may each have a value which is equal to or greater than the first spacing S1. In some embodiments, the first distance D1a may have a value which is the same as the first spacing S1. In some embodiments, the second distance D2a may have a value which is greater than the first spacing S1. In some embodiments, the first distance D1a may have a value which is less than the second distance D2a.

A width between the ground fence GF configured/provided by the plurality of electromagnetic shielding terminals 164 and an edge of the package base substrate 100a may include a first width W1a and a second width W2a. For example, the first width W1a may be a width between the edge of the package base substrate 100a and the ground fence GF in the long-axis direction, and the second width W2a may be a width between the edge of the package base substrate 100a and the ground fence GF in the short-axis direction. The first width W1a may have a value which is greater than the first distance D1a. The second width W2a may have a value which is less than the second distance D2a.

The plurality of electromagnetic shielding terminals 164 configuring/providing the ground fence GF and a dummy terminal 166 may be disposed symmetric about each of a first center line MAA, a second center line MIA, and a third center line DIA.

Referring to FIG. 7B, a semiconductor package 4-2 may include a plurality of electromagnetic shielding terminals 164 configuring/providing a ground fence GF. The plurality of electromagnetic shielding terminals 164 spaced apart from one another may be disposed to surround a real ball map RBMa configured/provided by a plurality of connection terminals 162.

The ground fence GF including the plurality of electromagnetic shielding terminals 164 may have a polygonal (e.g., quadrilateral/tetragonal) shape of which four vertexes are cut, and may surround the real ball map RBMa including the plurality of connection terminals 162. In some embodiments, some of the plurality of electromagnetic shielding terminals 164 may be spaced apart from one another by a first spacing S1, and others of the electromagnetic shielding terminals 164 may be spaced apart from one another by a second spacing S2 and may be disposed to surround the real ball map RBMa configured/provided by the plurality of connection terminals 162. The first spacing S1 may have a value which is less than the second spacing S2. In some embodiments, some electromagnetic shielding terminals 164, disposed in a vertex portion of the ground fence GF, of the plurality of electromagnetic shielding terminals 164 may be spaced apart from one another by the second spacing S2, and others of the electromagnetic shielding terminals 164 may be spaced apart from one another by the first spacing S1.

A distance between the real ball map RBMa configured/provided by the plurality of connection terminals 162 and the ground fence GF configured/provided by the plurality of electromagnetic shielding terminals 164 may include a first distance D1b and a second distance D2b. The first distance D1b and the second distance D2b may each have a value which is equal to or greater than the first spacing S1 and the second spacing S2. In some embodiments, the first distance D1b and the second distance D2b may each have a value which is greater than the first spacing S1 and the second spacing S2. In some embodiments, the first distance D1b may have a value which is less than the second distance D2b.

A width between the ground fence GF configured/provided by the plurality of electromagnetic shielding terminals 164 and an edge of a package base substrate 100a may include a first width W1b and a second width W2b. The first width W1b may have a value which is greater than the first distance D1b, and the second width W2b may have a value which is less than the second distance D2b.

The plurality of electromagnetic shielding terminals 164 configuring/providing the ground fence GF and a dummy terminal 166 may be disposed symmetric about each of a first center line MAA, a second center line MIA, and a third center line DIA.

Referring to FIG. 7C, a semiconductor package 4-3 may include a plurality of electromagnetic shielding terminals 164 configuring/providing a ground fence GF. The plurality of electromagnetic shielding terminals 164 spaced apart from one another may be disposed to surround a real ball map RBMa configured/provided by a plurality of connection terminals 162.

The ground fence GF including the plurality of electromagnetic shielding terminals 164 may have a polygonal (e.g., quadrilateral/tetragonal) shape of which four vertexes are cut, and may surround the real ball map RBMa including the plurality of connection terminals 162. In some embodiments, some of the plurality of electromagnetic shielding terminals 164 may be spaced apart from one another by a first spacing S1, and others of the electromagnetic shielding terminals 164 may be spaced apart from one another by a second spacing S2 and may be disposed to surround the real ball map RBMa configured/provided by the plurality of connection terminals 162. The first spacing S1 may have a value which is less than the second spacing S2. In some embodiments, some electromagnetic shielding terminals 164, disposed in a vertex portion of the ground fence GF, of the plurality of electromagnetic shielding terminals 164 may be spaced apart from one another by the second spacing S2, and others of the electromagnetic shielding terminals 164 may be spaced apart from one another by the first spacing S1.

A distance between the real ball map RBMa configured/provided by the plurality of connection terminals 162 and the ground fence GF configured/provided by the plurality of electromagnetic shielding terminals 164 may include a first distance D1c and a second distance D2c. The first distance D1c and the second distance D2c may each have a value which is equal to or greater than the first spacing S1 and the second spacing S2. In some embodiments, the first distance D1c and the second distance D2c may each have a value which is greater than the first spacing S1 and the second spacing S2. In some embodiments, the first distance D1c may have a value which is less than the second distance D2c.

A width between the ground fence GF configured/provided by the plurality of electromagnetic shielding terminals 164 and an edge of a package base substrate 100 may include a first width W1c and a second width W2c. The first width W1c may have a value which is greater than the first distance D1c. The second width W2c may have a value which is less than the second distance D2c.

The plurality of electromagnetic shielding terminals 164 configuring/providing the ground fence GF may be disposed symmetric about each of a first center line MAA, a second center line MIA, and a third center line DIA.

Referring to FIG. 7D, a semiconductor package 4-4 may include a plurality of electromagnetic shielding terminals 164 configuring/providing a ground fence GF. The plurality of electromagnetic shielding terminals 164 spaced apart from one another may be disposed to surround a real ball map RBMa configured/provided by a plurality of connection terminals 162.

The ground fence GF including the plurality of electromagnetic shielding terminals 164 may have a polygonal (e.g., quadrilateral/tetragonal) shape of which four vertexes are cut, and may surround the real ball map RBMa including the plurality of connection terminals 162. In some embodiments, the plurality of electromagnetic shielding terminals 164 may be spaced apart from one another by a first spacing S1 and may be disposed to surround the real ball map RBMa configured/provided by the plurality of connection terminals 162.

A distance between the real ball map RBMa configured/provided by the plurality of connection terminals 162 and the ground fence GF configured/provided by the plurality of electromagnetic shielding terminals 164 may include a first distance D1d and a second distance D2d. The first distance D1d and the second distance D2d may each have a value which is equal to or greater than the first spacing S1. In some embodiments, the first distance D1d may have a value which is the same as the first spacing S1. In some embodiments, the second distance D2d may have a value which is greater than the first spacing S1. In some embodiments, the first distance D1d may have a value which is less than the second distance D2d.

A width between the ground fence GF configured/provided by the plurality of electromagnetic shielding terminals 164 and an edge of a package base substrate 100a may include a first width W1d and a second width W2d. The first width W1d may have a value which is greater than the first distance D1d. The second width W2d may have a value which is less than the second distance D2d.

The plurality of electromagnetic shielding terminals 164 configuring/providing the ground fence GF and a dummy terminal 166 may be disposed symmetric about each of a first center line MAA, a second center line MIA, and a third center line DIA.

The ground fence GF illustrated in FIGS. 7A to 7D may have a structure similar to that of the ground fence GF illustrated in FIG. 2A, but is not limited thereto. For example, the ground fence GF illustrated in FIGS. 7A to 7D may have a structure similar to that of the ground fence GF illustrated in FIGS. 2B to 2F or the ground fence GF illustrated in FIGS. 4A and 4B. Also, the plurality of test pads 122 illustrated in FIG. 6A may be disposed in a region surrounded by the ground fence GF illustrated in FIGS. 7A to 7D.

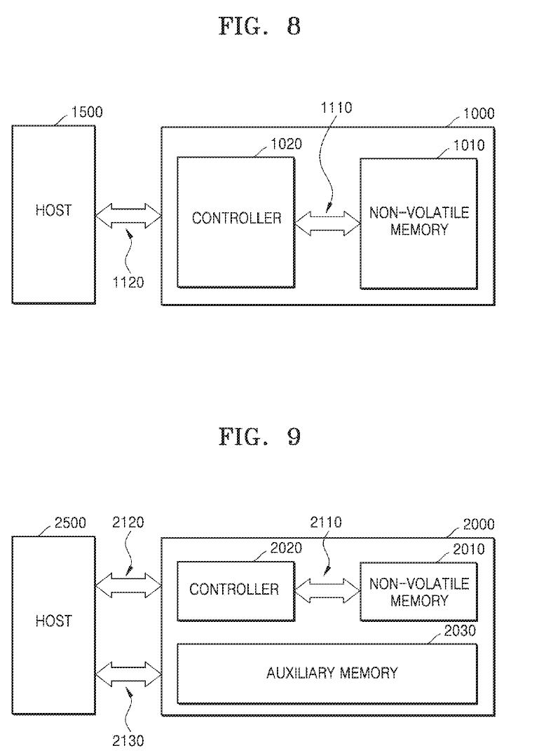

FIGS. 8 and 9 are schematic views illustrating a relationship between an external system and a semiconductor package according to some embodiments.

Referring to FIG. 8, data input from an external system 1500 (shown as host) may be stored in a semiconductor package 1000. The semiconductor package 1000 may include a non-volatile memory 1010 and a controller 1020.

The data input from the external system 1500 may be transferred to the controller 1020 through a host interface 1120 and may be stored in the non-volatile memory 1010 through a NAND interface 1110 by the controller 1020. Also, the controller 1020 may read data from the non-volatile memory 1010 through the NAND interface 1110 and may transmit the read data to the external system 1500 through the host interface 1120.

The semiconductor package 1000 may be one of the semiconductor packages 1a, 1b, 1-1 to 1-6, 2, 2-1, 2-2, 3, and 4-1 to 4-4 described above with reference to FIGS. 1B, 1C, and 3 to 7D. The non-volatile memory 1010 may be one of the first semiconductor chips 212 described above with reference to FIGS. 1B, 1C, and 5. The controller 1020 may be one of the second semiconductor chips 214 described above with reference to FIGS. 1B, 1C, and 5.

Referring to FIG. 9, data input from an external system 2500 (shown as host) may be stored in a semiconductor package 2000. The semiconductor package 2000 may include a non-volatile memory 2010, a controller 2020, and an auxiliary memory 2030.

Some pieces of data input from the external system 2500 may be transferred to the controller 2020 through a host interface 2120 and may be stored in the non-volatile memory 2010 through a NAND interface 2110 by the controller 2020. Also, the controller 2020 may read data from the non-volatile memory 2010 through the NAND interface 2110 and may transmit the read data to the external system 2500 through the host interface 2120.

Some pieces of data input from the external system 2500 may be stored in the auxiliary memory 2030 through a DRAM interface 2130. Also, data stored in the auxiliary memory 2030 may be transmitted to the external system 2500 through the DRAM interface 2130.

The semiconductor package 2000 may be one of the semiconductor packages 1c, 1-1 to 1-6, 2, 2-1, 2-2, 3 and 4-1 to 4-4 described above with reference to FIGS. 1D, 2A to 2F, 4A, 4B, and 6 to 7D. The non-volatile memory 2010 may be the first semiconductor chip 212 described above with reference to FIG. 1D. The controller 2020 may be the second semiconductor chip 214 described above with reference to FIG. 1D. The auxiliary memory 2030 may be the third semiconductor chip 216 described above with reference to FIG. 1D.

As described above, since the semiconductor package according to some embodiments may include the electromagnetic shielding member based on conformal shielding, the semiconductor package may be miniaturized, and an electromagnetic wave radiated through a space between the set board and the package base substrate may be shielded by the ground plate layer and the ground fence configured/provided by the plurality of electromagnetic shielding terminals. Accordingly, reliability may be protected/prevented from being reduced by a problem/disorder such as electromagnetic noise or a malfunction which occurs in an electronic device including the semiconductor package due to the semiconductor package.

Although the present inventive concepts have been particularly shown and described with reference to example embodiments thereof, it will be understood by those of ordinary skill in the art that various changes in form and details may be made therein without departing from the spirit and scope of the present disclosure as defined by the following claims.

What is claimed is:

1. A semiconductor package comprising:
a package base substrate comprising a base layer, a plurality of connection terminals on a first side of the base layer, and a plurality of electromagnetic shielding terminals spaced apart from one another on the first side of the base layer to provide a perimeter around the plurality of connection terminals;
a package body on a second side of the base layer that is opposite the first side, the package body comprising at least one semiconductor chip; and
an electromagnetic shielding layer on a surface of the package base substrate and on first and second surfaces of the package body,
wherein a value of a shortest distance between the plurality of connection terminals and the plurality of electromagnetic shielding terminals is equal to or higher than a separation distance between two adjacent ones of the plurality of electromagnetic shielding terminals.

2. The semiconductor package of claim 1, further comprising:
a ground plate layer extending along a portion of the first side of the base layer from an edge of the first side of the base layer,
wherein the ground plate layer is between the base layer and the plurality of electromagnetic shielding terminals, and
wherein the plurality of electromagnetic shielding terminals is electrically connected to the ground plate layer.

3. The semiconductor package of claim 2, wherein the electromagnetic shielding layer is electrically connected to the ground plate layer by contact with a side surface of the ground plate layer.

4. The semiconductor package of claim 2,
wherein the plurality of electromagnetic shielding terminals are on a lowermost surface of the ground plate layer, and
wherein the electromagnetic shielding layer extends lower than the lowermost surface of the ground plate layer.

5. The semiconductor package of claim 2, further comprising:
a solder resist layer on a portion of the ground plate layer,
wherein the portion of the ground plate layer is between the solder resist layer and the base layer, and
wherein the electromagnetic shielding layer is on a side surface of the solder resist layer.

6. The semiconductor package of claim 2, further comprising:
a dummy terminal on a through hole that separates first and second portions of the ground plate layer.

7. The semiconductor package of claim 1,
wherein the separation distance between the two adjacent ones of the plurality of electromagnetic shielding terminals comprises a first spacing or a second spacing,
wherein first ones of the plurality of electromagnetic shielding terminals are spaced apart from one another by the first spacing, and second ones of the plurality of electromagnetic shielding terminals are spaced apart from one another by the second spacing, the second spacing being longer than the first spacing, and
wherein the value of the shortest distance between the plurality of connection terminals and the plurality of electromagnetic shielding terminals is higher than the first spacing and the second spacing.

8. The semiconductor package of claim 7, wherein adjacent ones of the first ones of the plurality of electromagnetic shielding terminals that are spaced apart from one another by the first spacing are adjacent a center line extending in a long-axis direction of the package base substrate.

9. The semiconductor package of claim 1, wherein the plurality of electromagnetic shielding terminals are symmetric about each of a first center line extending in a long-axis direction of the package base substrate and a second center line extending in a short-axis direction of the package base substrate.

10. The semiconductor package of claim 1, wherein the plurality of electromagnetic shielding terminals are symmetric about a first center line extending in a diagonal direction and are asymmetric about each of a second center line extending in a long-axis direction of the package base substrate and a third center line extending in a short-axis direction of the package base substrate.

11. A semiconductor package comprising:
a package base substrate comprising a bridge region, a fence region around the bridge region, a spacing region between the bridge region and the fence region, an edge region around the fence region, a base layer, a plurality of connection terminals on a lower surface of the base layer, a ground plate layer on an end portion of the lower surface of the base layer, and a plurality of electromagnetic shielding terminals electrically connected to the ground plate layer in the fence region around the plurality of connection terminals;
a package body on the package base substrate, the package body comprising a plurality of semiconductor chips; and
an electromagnetic shielding layer on a side surface of the package base substrate and a side surface and an upper surface of the package body and contacting a side surface of the ground plate layer,
wherein a width of the spacing region is equal to or greater than a separation distance between two adjacent ones of the plurality of electromagnetic shielding terminals.

12. The semiconductor package of claim 11,
wherein the plurality of semiconductor chips comprises a first semiconductor chip and a second semiconductor chip,
wherein the first semiconductor chip is electrically connected to the second semiconductor chip through a NAND interface,
wherein the second semiconductor chip is electrically connected to first ones of the plurality of connection terminals through a host interface, and
wherein the semiconductor package further comprises a plurality of test pads on the lower surface of the base layer in at least one of the spacing region or the bridge region and electrically connected to the NAND interface.

13. The semiconductor package of claim 12, wherein the plurality of semiconductor chips further comprises a third semiconductor chip electrically connected to second ones of the plurality of connection terminals through a DRAM interface.

14. The semiconductor package of claim 11, wherein the plurality of electromagnetic shielding terminals comprises two rows of the plurality of electromagnetic shielding terminals along a periphery of the plurality of connection terminals.

15. The semiconductor package of claim 14, wherein the plurality of electromagnetic shielding terminals defines a zigzag pattern along a periphery of the plurality of connection terminals.

16. The semiconductor package of claim 11,
wherein a ratio of a first width of the edge region to a first width of the spacing region in a long-axis direction of the package base substrate is greater than one, and
wherein a ratio of a second width of the edge region to a second width of the spacing region in a short-axis direction of the package base substrate is less than one.

17. A semiconductor package comprising:
a package base substrate comprising a base layer, a plurality of connection terminals on a bottom of the base layer to provide a ball map, a ground plate layer on the bottom of the base layer, and a plurality of electromagnetic shielding terminals attached to a bottom of the ground plate layer, the plurality of electromagnetic shielding terminals being spaced apart from one another to provide a ground fence around the ball map;
a package body on the package base substrate, the package body comprising a plurality of semiconductor chips and an encapsulation layer that is on a top of the package base substrate and is on the plurality of semiconductor chips; and
an electromagnetic shielding layer on a side surface of the package base substrate and a side surface and a top of the package body and contacting the ground plate layer,
wherein a shortest distance between the ball map and the ground fence is equal to or greater than a separation distance between two adjacent ones of the plurality of electromagnetic shielding terminals.

18. The semiconductor package of claim 17, further comprising:
a bottom solder resist layer on a portion of the ground plate layer that is on the bottom of the base layer,
wherein the electromagnetic shielding layer extends lower than the bottom of the ground plate layer and is on a side surface of the bottom solder resist layer.

19. The semiconductor package of claim 17, wherein the ground fence comprises a polygonal shape comprising four vertex portions around the ball map.

20. The semiconductor package of claim 19, further comprising:
four dummy terminals in the four vertex portions, respectively, of the ground fence,
wherein the four dummy terminals are electrically insulated from the ground plate layer.
